(19) United States
(12) Patent Application Publication
(10) Pub. No.: US 2026/0025152 A1
(43) Pub. Date: Jan. 22, 2026

(54) TRELLIS ASSISTED BIT FLIPPING DECODER

(71) Applicant: SK hynix Inc., Gyeonggi-do (KR)

(72) Inventors: Fan Zhang, Fremont, CA (US); Meysam Asadi, Livermore, CA (US); Haobo Wang, San Jose, CA (US)

(21) Appl. No.: 18/778,422

(22) Filed: Jul. 19, 2024

(51) Int. Cl. H03M 13/25; H03M 13/00

(52) U.S. Cl. CPC H03M 13/255; H03M 13/256; H03M 13/611

(57) ABSTRACT

Techniques related to improving the error correction performance of a bit-flipping (BF) decoder for decoding a codeword using one or more trellis decoders are described. In some examples, the BF decoder can identify a set of unsatisfied check nodes among a set of check nodes that can be decoded using a trellis decoder. The trellis decoder can perform trellis decoding on the set of unsatisfied check nodes and variable nodes connected to the set of unsatisfied check nodes to determine bit values of the variable nodes to resolve the set of unsatisfied check nodes identified by the BF decoding. The BF decoder can use the bit values of the variable nodes determined by the trellis decoding in a next iteration of the BF decoding to decode the codeword.

### BACKGROUND

Error-correction codes (ECCs) are frequently used for various types of data storage devices such as NAND flash memories. ECCs are also frequently used during the process of data transmission. ECC refers to codes that add redundant data, or parity data, to a message, such that the message can be recovered by a receiver equipped with a decoder even when one or more errors were introduced, either during the process of transmission, or storage. In general, an ECC decoder can correct a limited number of errors, with the number depending on the type of code used and/or the error correction capability of the decoder itself.

Low-density parity-check (LDPC) codes are an example of an ECC. In ECC decoding, including LDPC decoding, there is often a tradeoff between error correction capability (e.g., number of bits that can be corrected) and computation cost (e.g., power consumption or processing time). Generally, the higher the error correction capability, the more complex the decoding processing and the higher the power consumption and/or processing time. Bit flipping (BF) decoders and min-sum (MS) decoders are examples of ECC decoders that can perform decoding of LDPC codes. Compared to more complex decoders such as MS decoders, BF decoders are significantly faster but have lower error correction capability.

### BRIEF SUMMARY

Techniques related to improving the error correction performance of a bit flipping (BF) decoder by using a trellis decoder to assist with error decoding are described. A trellis-assisted BF decoder can provide improved decoding especially for irregular parity-check matrices. Generally, irregular codes are used to get better correction performance from an MS decoder. For an irregular code, the column weight, or column degree, or number of non-zero elements in a column, can vary across different columns. A good irregular code for a MS decoder typically leads to poor BF correction performance. A BF decoder may not perform as well for low degree nodes because the information available for making a flipping decision is limited by the degree of the nodes.

In an example, a method for decoding a low-density parity-check (LDPC) codeword involves performing BF decoding to identify a set of unsatisfied check nodes among a set of check nodes. The set of check nodes represents a result of applying parity-check equations to the LDPC codeword. The method further involves performing trellis decoding on the set of unsatisfied check nodes and variable nodes connected to the set of unsatisfied check nodes to determine bit values of the variable nodes to resolve the set of unsatisfied check nodes identified by the BF decoding. The method further involves using the bit values of the variable nodes determined by the trellis decoding in a next iteration of the BF decoding to decode the LDPC codeword.

In an example method, the bit values of the variable nodes are determined based on the lowest path cost metric of the trellis decoding to resolve the set of unsatisfied check nodes.

In an example method, the trellis decoding includes executing a trellis decoder having states represented by the set of unsatisfied check nodes, and state transition stages represented by the variable nodes.

In an example method, the BF decoding can be performed concurrently with the trellis decoding.

In an example method, the trellis decoding includes concurrently executing multiple trellis decoders. Each of the multiple trellis decoders can have states represented by a different subset of the set of unsatisfied check nodes, and state transition stages represented by the variable nodes. In an example, each of the multiple trellis decoders can have states represented by at least one unsatisfied check node in the set of unsatisfied check nodes and at least one satisfied check node, and state transition stages represented by the variable nodes, and each of the at least one satisfied check node shares a minimum threshold number of connected variable nodes with the at least one unsatisfied check node.

In an example method, when the trellis decoding includes concurrently executing multiple trellis decoders having states represented by overlapping subsets of the set unsatisfied check nodes, the bit values of variable nodes having conflicting bit values determined by different trellis decoders can be decided by a majority vote of the trellis decoders.

In an example, a device (e.g., a storage device) may include a memory storing an LDPC codeword. The device further includes one or more processing units operable to perform BF decoding to identify a set of unsatisfied check nodes among a set of check nodes. The set of check nodes represents a result of applying parity-check equations to the LDPC codeword read from the memory. The one or more processing units are further operable to perform trellis decoding on the set of unsatisfied check nodes and variable nodes connected to the set of unsatisfied check nodes to determine bit values of the variable nodes to resolve the set of unsatisfied check nodes identified by the BF decoding. The one or more processing units are further operable to use the bit values of the variable nodes determined by the trellis decoding in a next iteration of the BF decoding to decode the LDPC codeword. The device can also perform similar operations as the example methods described above.

These illustrative examples are mentioned not to limit or define the disclosure but to provide examples to aid understanding thereof. Additional embodiments and examples are discussed in the Detailed Description, and further description is provided there.

### BRIEF DESCRIPTION OF THE DRAWINGS

An understanding of the nature and advantages of various embodiments may be realized by reference to the following figures. In the appended figures, similar components or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

FIG. 1 illustrates an example high level block diagram of an error correction system, in accordance with certain embodiments of the present disclosure.

FIGS. 2A and 2B illustrate an example parity-check matrix and an example graph representing the parity-check matrix, in accordance with certain embodiments of the present disclosure.

FIG. 3 illustrates an example error correction system that includes multiple decoders, in accordance with certain embodiments of the present disclosure;

FIGS. 4A-4E illustrate an example of a series of state transitions for a trellis decoding process to resolve a set of unsatisfied check nodes, according to an aspect of the disclosure.

FIG. 5 illustrates an example of a trellis decoding process that generates a trellis with a lowest path cost metric, according to some embodiments.

FIG. 6 illustrates a flow diagram of an example process for decoding a codeword, in accordance with certain embodiments of the present disclosure.

FIG. 7 illustrates an example architecture of a computer system, in accordance with certain embodiments of the present disclosure.

FIG. 8 illustrates an example of a computer system usable for implementing one or more embodiments of the present disclosure.

### DETAILED DESCRIPTION

In the following description, for the purposes of explanation, specific details are set forth in order to provide a thorough understanding of certain inventive embodiments. However, it will be apparent that various embodiments may be practiced without these specific details. The figures and description are not intended to be restrictive.

Low-density parity-check (LDPC) codes are linear block codes defined by a sparse parity-check matrix H, which consists of zeros and ones. The term “sparse matrix” may refer to a matrix in which a number of non-zero values in each column and each row is much less than its dimension. The term “column weight” may refer to the number of non-zero values in a specific column of the parity-check matrix H. The term “row weight” may refer to a number of non-zero values in a specific row of the parity-check matrix H. In general, if column weights of all the columns in a parity-check matrix corresponding to an LDPC code are similar, the code can be referred to as a “regular” LDPC code. On the other hand, an LDPC code can be deemed “irregular” if at least one of the column weights is different from other column weights. Usually, irregular LDPC codes can provide better error protection than regular LDPC codes.

In some memory storage devices such as solid state drives (SSDs), most of the error correction workload is performed by the bit flipping (BF) decoders in comparison to the min-sum (MS) decoders. Generally, BF decoders converge quickly for most of the traffic, leaving only a small percentage of traffic to be handled by the MS decoders. For example, BF decoders can provide faster results for error correction that meets the system specifications and/or customer requirements (e.g., power, area, and/or timing budgets). However, BF decoders may not perform well for irregular LDPC codes. As an example, BF decoders may quickly correct most of the errors, but may take much longer (e.g., multiple iterations of decoding), or even fail to correct a small set of errors (e.g., a trapping set of errors). In some implementations, an MS decoder can be used to correct that set of errors. However, MS decoding is generally slow and may not meet the timing budgets based on the specification or performance requirements of the storage device.

Furthermore, as more bits per cell are introduced in NAND flash memory devices, and more layers are stacked, the NAND flash memory devices get noisier, and stronger correction is desired of the MS decoders. In some implementations, the parity check matrix can be optimized to improve the correction performance of MS decoders. However, optimized parity check matrices for MS decoders can significantly degrade the correction performance of the BF decoders, which may require designing fasters MS decoders at the expense of larger power and chip area.

Techniques related to improving the correction performance by using a trellis-assisted BF decoder are described. For example, a trellis decoder can assist the basic BF decoder to overcome the weaknesses of the basic BF decoder in processing irregular LDPC codes. In particular, examples are described which relate to using the trellis decoder to correct a small set of errors that were identified by the basic BF decoder. In various embodiments, trellis decoding can be performed concurrently with the BF decoding by executing multiple trellis decoders to handle different subsets of errors in parallel, while the basic BF decoder continues to perform decoding of the codewords. Results of the trellis decoding can be used by the basic BF decoder to improve the error correction capability of the basic BF decoder without introducing additional delays.

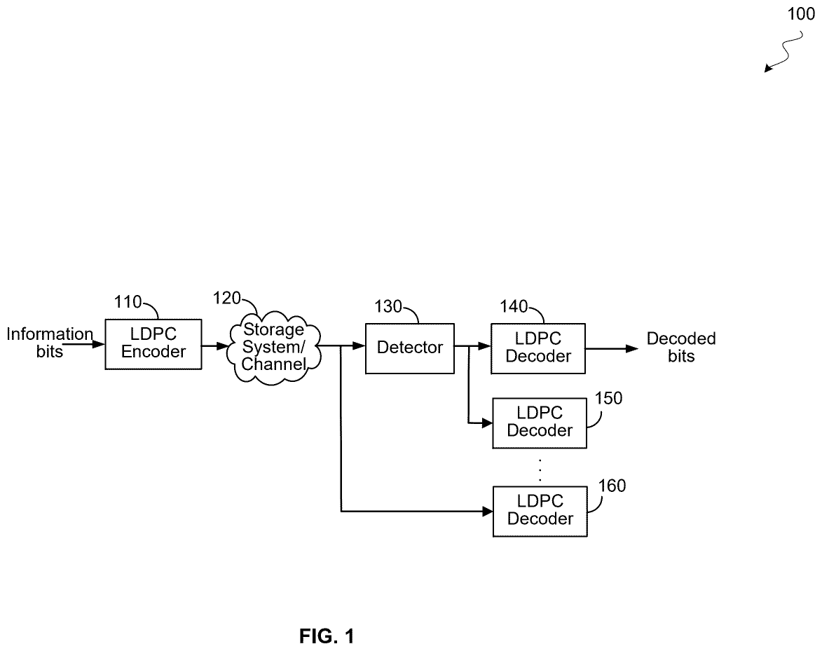

FIG. 1 illustrates an example high level block diagram of an error correction system 100, in accordance with certain embodiments of the present disclosure. In the example, LDPC codes are described in connection with data storage. However, the embodiments of the present disclosure are not limited as such. Instead, the embodiments similarly apply to other usages of LDPC codes including, for example, data transmission. Further, the embodiments of the present disclosure can similarly apply to other error correction codes for which unreliable check nodes can be identified.

As described previously, LDPC codes are linear block codes defined by a sparse parity-check matrix H, which consists of zeros and ones. LDPC codes are also classified according to the way they are constructed. Random computer searches or algebraic constructions are possible. The random computer search construction describes an LDPC code having a parity-check matrix designed by a random computer-based procedure. Algebraic construction implies that the parity-check matrix has been constructed based on combinatorial methods. Quasi-cyclic LDPC (QC-LDPC) codes fall under the latter construction method. One advantage of QC-LDPC codes is that they have a relatively easier implementation in terms of the encoding procedure. The main feature of QC-LDPC codes is that the parity-check matrix consists of circulant submatrices, which could be either based on an identity matrix or a smaller random matrix. Permutation vectors could also be used in order to create the circulant submatrices.

As illustrated, an LDPC encoder 110 receives information bits that include data which is to be stored in a storage system 120. LDPC encoded data is output by the LDPC encoder 110 and is written to the storage system 120. In various embodiments, the storage system 120 may include a variety of storage types or media such as (e.g., magnetic) disk drive storage, flash storage, etc. In some embodiments, the techniques are employed in a transceiver and instead of being written to or read from storage, the data is transmitted and received over a wired and/or wireless channel. In such implementations, the errors in the received codeword may be introduced during transmission of the codeword.

When the stored data is requested or otherwise desired (e.g., by an application or user), a detector 130 receives data from the storage system 120. The received data may include some noise or errors. The detector 130 performs detection on the received data and outputs decision and/or reliability information. For example, a soft output detector outputs reliability information and a decision for each detected bit. On the other hand, a hard output detector outputs a decision on each bit without providing corresponding reliability information. As an example, a hard output detector may output a decision that a particular bit is a “1” or a “0” without indicating how certain or sure the detector is in that decision. In contrast, a soft output detector outputs a decision and reliability information associated with the decision. In general, a reliability value indicates how certain the detector is in a given decision. In one example, a soft output detector outputs a log-likelihood ratio (LLR) where the sign indicates the decision (e.g., a positive value corresponds to a “1” decision and a negative value corresponds to a “0” decision) and the magnitude indicates how certain the detector is in that decision (e.g., a large magnitude indicates a high reliability or certainty).

The decision and/or reliability information is passed to an LDPC decoder 140 which performs LDPC decoding using the decision and reliability information. A soft input decoder utilizes both the decision and the reliability information to decode the codeword. A hard decoder utilizes only the decision values in the decoder to decode the codeword. The decoded bits generated by the LDPC decoder 140 are passed to the appropriate entity (e.g., the user or application which requested it). With proper encoding and decoding, the decision and the reliability information can be used to recover the correct decoded bits.

Although the output of the detector 130 may be beneficial for some LDPC decoders, not all error correction systems are configured with a detector. Further, the processing performed by detector 130 may be computation intensive, especially in regard to computing reliability information, which could significantly offset the advantages of using faster decoders such as BF decoders. Accordingly, in some implementations, LLR or other reliability information provided by a detector such as the detector 130 is not used as input to a BF decoder. Instead, the BF decoder may be configured to determine reliability for itself, e.g., through identifying unreliable check nodes using suitable techniques. However, the output of detector 130 may still be used for generating input to other decoders in the error correction system.

The error correction system 100 may include multiple ECC or LDPC decoders that form a decoder hierarchy in which decoding is first attempted using a faster and/or less complex decoder (e.g., a BF decoder) before resorting to a slower and/or more complex decoder (e.g., a MS decoder). Accordingly, the error correction system 100 may include one or more additional LDPC decoders (e.g., LDPC decoder 150 and LDPC decoder 160), where at least some of the additional LDPC decoders do not receive output of the detector 130 (e.g., LDPC decoder 160, as shown in FIG. 1).

In various embodiments, an error correction system such as the system 100 in FIG. 1 may be implemented using a variety of techniques including an application-specific integrated circuit (ASIC), a field-programmable gate array (FPGA), and/or a general purpose processor (e.g., an Advanced RISC Machine (ARM) core).

LDPC codes are usually represented by bipartite graphs. One set of nodes, the variable nodes (also referred to as bit nodes) correspond to elements of the codeword and the other set of nodes, e.g., check nodes, correspond to the set of parity-check constraints satisfied by the codeword. Typically, the edge connections are chosen at random. The error correction capability of an LDPC code is improved if cycles of short length are avoided in the graph. In an (r,c) regular code, each of the n variable nodes (e.g., V₀, V₁, V₂ . . . Vₙ₋₁) has connections to r check nodes, and each of the m check nodes (e.g., C₀, C₁, C₂ . . . Cₘ₋₁) has connections to c variable nodes. Each check node represents a result of applying a separate parity-check equation. Thus, r corresponds to the number of parity-check equations involving each code bit and also the degree of each variable node. Similarly, c corresponds to the number of code bits involved in each parity-check equation and also the degree of each check node. The number of variable nodes (n) corresponds to the total number of bits (data and parity) in the code, i.e., the codeword length. In an irregular LDPC code, the check node degree is not uniform.

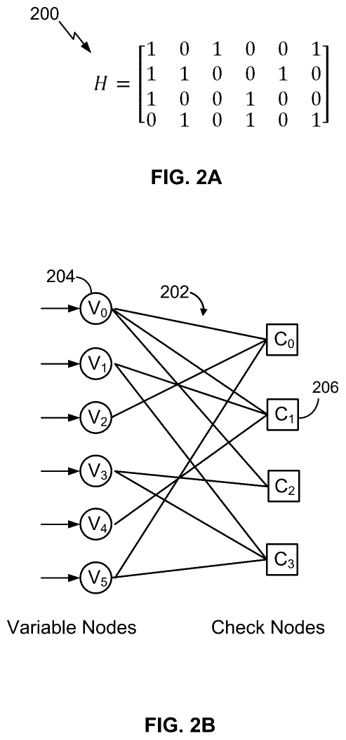

FIG. 2A illustrates an example parity-check matrix H 200 and FIG. 2B illustrates an example bipartite graph corresponding to the parity-check matrix 200, in accordance with certain embodiments of the present disclosure. In this example, the parity-check matrix 200 has six column vectors and four row vectors. In practice, parity-check matrices tend to be much larger. Network 202 forms a bipartite graph representing the parity-check matrix 200. Various types of bipartite graphs are possible, including, for example, a Tanner graph. In some examples, the parity-check matrix H 200 may include circulant submatrices, and each circulant submatrix may correspond to a matrix within the parity-check matrix H 200, where the different columns of this matrix have the same weight.

Generally, the variable nodes in the network 202 correspond to the column vectors in the parity-check matrix 200. The check nodes in the network 202 correspond to the row vectors of the parity-check matrix 200. The interconnections between the nodes are determined by the values of the parity-check matrix 200. Specifically, a “1” indicates that the check node and variable node at the corresponding row and column position have a connection. A “0” indicates there is no connection. For example, the “1” in the leftmost column vector and the second row vector from the top in the parity-check matrix 200 corresponds to the connection between a variable node V0 204 and a check node C1 206 in FIG. 2B. Collectively, the check nodes represent a syndrome computed through applying the parity-check equations represented by the parity-check matrix 200 to the received codeword. A syndrome weight (also known as a checksum) can be computed by summing together the bit-values of all the check nodes.

A message passing algorithm can be used to decode LDPC codes. Several variations of the message passing algorithm exist in the art, such as min-sum (MS) algorithm, sum-product algorithm (SPA) or the like. Message passing uses a network of variable nodes and check nodes, as shown in FIG. 2B. The connections between variable nodes and check nodes are described by and correspond to the values of the parity-check matrix 200, as shown in FIG. 2A. The content of a message passed from a variable node to a check node or vice versa depends on the message passing algorithm used.

A hard decision message passing algorithm may be performed in some instances. In a first step, each of the variable nodes sends a message to one or more check nodes that are connected to it. In this case, the message is a value that each of the variable nodes believes to be its correct value. The values of the variable nodes may be initialized according to the received codeword.

In the second step, each of the check nodes calculates a response to send to the variable nodes that are connected to it using the information that it previously received from the variable nodes. This step can be referred to as the check node update (CNU). The response message corresponds to a value that the check node believes that the variable node should have based on the information received from the other variable nodes connected to that check node. This response is calculated using the parity-check equations which force the values of all the variable nodes that are connected to a particular check node to sum up to zero (modulo 2).

At this point, if all the equations at all the check nodes are satisfied, meaning the value of each check node is zero, then the resulting checksum is also zero, so the decoding algorithm declares that a correct codeword is found and decoding terminates. If a correct codeword is not found (e.g., the value of any check node is one), the iterations continue with another update from the variable nodes using the messages that they received from the check nodes to decide if the bit at their position should be a zero or a one, e.g., using a majority voting rule in which the value of a variable node is set to the value of a majority of the check nodes connected to the variable node. The variable nodes then send this hard decision message to the check nodes that are connected to them. The iterations continue until a correct codeword is found, a certain number of iterations are performed depending on the syndrome of the codeword (e.g., of the decoded codeword), or a maximum number of iterations are performed without finding a correct codeword. It should be noted that a soft-decision decoder works similarly, however, each of the messages that are passed among check nodes and variable nodes can also include reliability information for each bit.

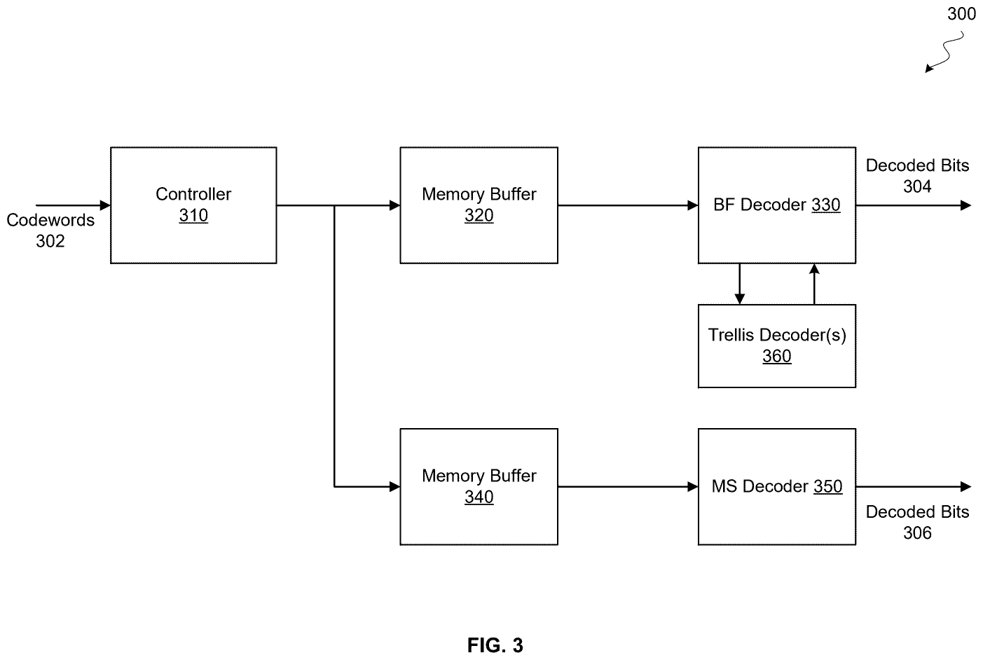

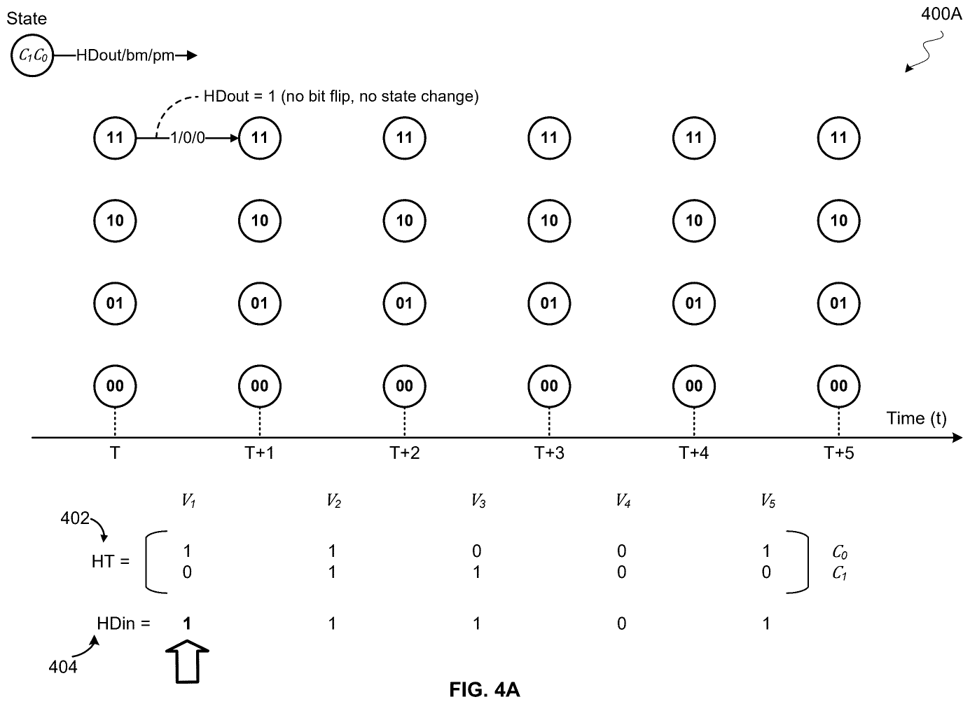

FIG. 3 illustrates an example error correction system 300 that includes multiple decoders, in accordance with certain embodiments of the present disclosure. The error correction system 300 can be included in a memory device, such as an SSD. In turn, the error correction system 300 includes a controller 310, a memory buffer 320 corresponding to a BF decoder 330, and a memory buffer 340 corresponding to an MS decoder 350. The controller 310 can determine which of the two decoders 330 and 350 are to be used to decode different codewords 302 based on an estimate of the number of raw bit-errors for each of the codewords. The bit-errors can be due to noise and, accordingly, the codewords 302 can include noisy codewords. The BF decoder 330 outputs decoded bits 304 corresponding to one or more of the codewords 302, where the decoded bits 304 remove some or all of the noise (e.g., correct the error bits). Similarly, the MS decoder 350 outputs decoded bits 306 corresponding to remaining one or more of the codewords 302, where the decoded bits 306 remove some or all of the noise (e.g., correct the error bits).

If the controller 310 determines that a codeword has a severe bit error rate, a decoding failure is likely with the two decoders 330 and 350. In such instances, and assuming that the only decoders in the error correction system 300 are the decoders 330 and 350, the controller 310 may skip decoding altogether to, instead, output an error message. Otherwise, the codeword can be dispatched to the BF decoder 330 when the controller 310 determines that the bit-error rate falls within the error correction capability of the BF decoder 330. Alternatively, the codeword can be dispatched to the MS decoder 350 when the controller 310 determines that the bit-error rate is outside the error correction capability of the BF decoder 330 but within the error correction capability of the MS decoder 350. Dispatching the codeword includes storing the codeword into one of the memory buffers 320 or 340 depending on the controller's 310 determination. The memory buffers 320 and 340 are used because, in certain situations, the decoding latency is slower than the data read rate of a host reading the codewords 302.

Accordingly, over time, the codewords 302 are stored in different input queues for the BF decoder 330 and the MS decoder 350. For typical SSD usage, it is expected that most traffic would go to the BF decoder 330. Hence, improving the BF decoder can have a significant impact on the overall error correction performance. Although FIG. 3 illustrates only one low latency and high throughput decoder (BF decoder 330) and one high error correction capability decoder (MS decoder 350), a different number of decoders can be used. For instance, a second BF decoder can be also used and can have the same or a different configuration than the BF decoder 330.

In an example, the BF decoder 330 may process a fixed number “Wᵢ” of variable nodes in one clock-cycle. In other words, for each of the “Wᵢ” variable nodes to be processed in this cycle, the BF decoder 330 counts the number of neighboring check-nodes that are unsatisfied. As used herein, the term “neighboring” means directly connected via a single graph edge. Accordingly, neighboring check nodes for a given variable node are those check nodes which are directly connected to the variable node. However, in some implementations, a neighboring check node can be a check node that is farther away (e.g., connected through a path length of two).

The count of neighboring, unsatisfied check nodes is used to compute a numerical value of a flipping energy for the variable node. As described below, the flipping energy for at least some variable nodes can be computed taking into further account the total number of neighboring satisfied but unreliable check nodes. Once the flipping energy for a variable node has been computed, the BF decoder 330 compares this number to a flipping threshold. If the flipping energy is larger than the flipping threshold, the BF decoder 330 flips the current bit-value of the variable node. As an example, the flipping energy for the it bit can be calculated using the following equation:

$$E ( i ) = \sum \{ {∀}_{j} w / H ( i , j ) = 1 \} s\_old ( j ) + ( dec\_prev ( i ) ! = chn ( i ) ) ,$$

Where s_old is the syndrome, and dec_prey is the current value of the variable node, and chn(i) is the channel value. In some examples, the algorithm described by the above equation for calculating the flipping energy is called a basic BF algorithm due to the single bit/node flipping nature of the algorithm.

The processing of all the variable nodes of the LDPC codes for a single iteration may occur over multiple clock cycles. In examples featuring circulant submatrices, each clock cycle may involve computing flipping energies for variable nodes associated with one or more circulant submatrices and updating the bit-values of those variable nodes accordingly. In general, all circulant submatrices are processed over the course of a single iteration. At the end of the iteration, the BF decoder 330 updates the bit-values of the check nodes using the updated bit-values of the variable nodes, and the BF decoder 330 may proceed to the next iteration if any of the check nodes remain unsatisfied or a maximum allowable number of iterations has not yet been reached.

When irregular LDPC codes are used to improve the correction performance of the MS decoder 350, the number of non-zero elements in each column (e.g., column weight or column degree) can vary across different columns. A good irregular code for the MS decoder 350 may typically lead to poor correction performance of the BF decoder 330. For example, in some cases, the BF decoder 330 may not work well with low degree nodes (e.g., degree-3 variable nodes), since the information available to make a flipping decision is limited by the number of non-zero elements.

The BF decoder 330 is generally able to correct most of the errors in a first iteration. In some cases, a small set of check nodes (sometimes called a trapping set) may remain unsatisfied even after multiple iterations of error corrections have been attempted by the BF decoder 330. For example, some of the check nodes may keep oscillating or changing their bit values in each iteration. Each trapping set may represent an error pattern and can be a specific combination of variable nodes that, if the bit-values of all the variable nodes in the trapping set are in error, then the decoder will be unable to correct those errors.

A decoder with a higher error correction capability will have fewer trapping sets and/or larger-sized trapping sets compared to a decoder with a lower error correction capability. For example, conventional BF decoders have a greater number of trapping sets compared to MS decoders, resulting in code failures at lower failed-bit counts. As discussed above, one of the advantages of a BF decoder is its decoding speed. Using a decoder with higher error correction capability may not always be feasible due to additional decoding latency. BF decoders that use more complex message passing techniques (e.g., 2-bit wide messages, where one bit is used to signal node reliability) are another option but tend to be costly due to increased implementation complexity (e.g., higher logic-gate count) and increased power consumption.

Techniques described herein can be used to overcome the weakness of the BF decoder 330 by executing one or more trellis decoders 360 concurrently with the BF decoder 330 to resolve a set of unsatisfied check nodes. For example, the set of unsatisfied check nodes may include check nodes that oscillate during the BF decoding process, e.g., their values change during each iteration. The BF decoder 330 may identify a set of unsatisfied check nodes from a set of check nodes, and provide a small sub-matrix to the trellis decoder 360. The sub-matrix may include the set of unsatisfied check nodes, and variable nodes connected to the set of unsatisfied check nodes. The sub-matrix can be composed of portion(s) of the parity-check matrix.

The check nodes and variable nodes for performing the trellis decoding can be selected based on any suitable criteria. As an example, when the total checksum is low, some of the unsatisfied check nodes can be selected to be a part of the small sub-matrix. In another example, one unsatisfied check node and a few satisfied check nodes that are strongly connected to the unsatisfied check node can be selected. Two check nodes are considered to be strongly connected when they share a minimum threshold number of connected variable nodes. The check nodes selection can be at the bit-level, instead of at the circulant row level, which can be beneficial due to the random nature of the remaining errors and the complexity of the trellis decoder.

Trellis decoding may include executing a trellis decoder having states represented by the set of unsatisfied check nodes, and state transition stages represented by the variable nodes. For example, each check node can support 2 states, e.g., 0 and 1. Therefore, as the selected number of check nodes increase for trellis decoding, the possible number of states increases exponentially, which may slow down the trellis decoding process. Thus, in some embodiments, the sub-matrix provided by the BF decoder 330 for trellis decoding can be further partitioned into smaller sub-matrices, with each smaller sub-matrix comprising a subset of unsatisfied check nodes and variable nodes connected to the subset of unsatisfied check nodes. In this case, trellis decoding process may be accelerated by concurrently executing multiple trellis decoders with each of the multiple trellis decoders having states represented by a different subset of unsatisfied check nodes, and state transition stages represented by the variable nodes. In some implementations, partitioning of the small sub-matrix, and/or any thresholds for partitioning can be configured by the controller 310.

In some embodiments, each of the multiple trellis decoders may have states represented by at least one unsatisfied check node in the set of unsatisfied check nodes and at least one satisfied check node, and state transition stages represented by the variable nodes. Each of the at least one satisfied check node may share a minimum threshold number of connected variable nodes with the at least one unsatisfied check node. In some embodiments, the multiple trellis decoders may include a plurality of trellis decoders having states represented by overlapping subsets of the set of unsatisfied check nodes, and state transition stages represented by the variable nodes. Hence, one or more of the unsatisfied check nodes may belong to different subsets, and thus be decoded by different trellis decoders.

In some embodiments, multiple trellis decoders 360 can be executed concurrently with the BF decoder 330 to resolve small subsets of unsatisfied check nodes. At the end of the iteration, the bit-flips suggested by the trellis decoder(s) 360 can be applied on top of the hard decision of the basic BF decoder 330. If there is a conflict, e.g., different trellis decoders 360 suggest conflicting bit-flips, a majority vote can be applied across all trellis decoders 360, or an arbitrary tie-break can be applied.

A trellis can provide a time-indexed version of a state diagram where an input bit causes a state transition corresponding to a forward path in the trellis. Given an initial or a source state, every possible input sequence corresponds to a unique path in the trellis. In some implementations, Viterbi decoding may be used to construct the trellis, and branch metrics (bm) and path metrics (pm) may be calculated along the path to determine a minimum weight path through the entire trellis. A branch metric may represent a distance (e.g., hamming distance) between the received bit and the expected bit for each state transition stage (or arc) of the trellis. A path metric may represent a most likely path from the initial state to the current state. In some implementations, the path metric may represent a smallest hamming distance between the initial state and the current state measured over all possible paths between the two states. The path metric is an accumulative sum of all the branch metrics along the path, and can be calculated incrementally by summing the branch metrics of the previous state transition stages along the path. The path with the smallest Hamming distance generally indicates low bit error rate.

Referring back to FIG. 3, the BF decoder 330 may provide input bits HDᵢₙ to the trellis decoder 360 that correspond to the variable nodes connected to the set of unsatisfied check nodes in a sub-matrix HT. The trellis decoder 360 may perform trellis decoding to determine bit values of the variable nodes represented by an output HDₒᵤₜ to resolve the set of unsatisfied check nodes identified by the BF decoder 330 based on an algorithm, as described below.
1. Initialize path metric pm(s(0))=0 for state s(0)=1, . . . , 2\hat{ }r, where r is the number of check nodes under consideration. For example, the check nodes belong to the set of unsatisfied check nodes.
2. For t=1:n, where n is the number of columns in the HT sub-matrix:
   a. Construct outgoing branches from each state at time t based on:
      i. The next state s(t+1) is equal to the source state s(t) for HDᵢₙ(t)=0
      ii. The next state s(t+1) is XOR(source state, HT(:,t)) for HDᵢₙ(t)=1
      iii. The branch metric bm(HDₒᵤₜ(t)) is equal to

$$( {HD}_{out} ( t ) ) == ( {HD}_{in} ( t ) ) ? 0 : 1$$

iv. The path metric pm(s(t+1))=pm(s(t)+bm(HDₒᵤₜ(t))).
b. For each destination state, if there are multiple branches going to it, set pm(s(t+1))=min(pm(s(t))) for all incoming branches and set HDₒᵤₜ(t) to be from the winner branch.

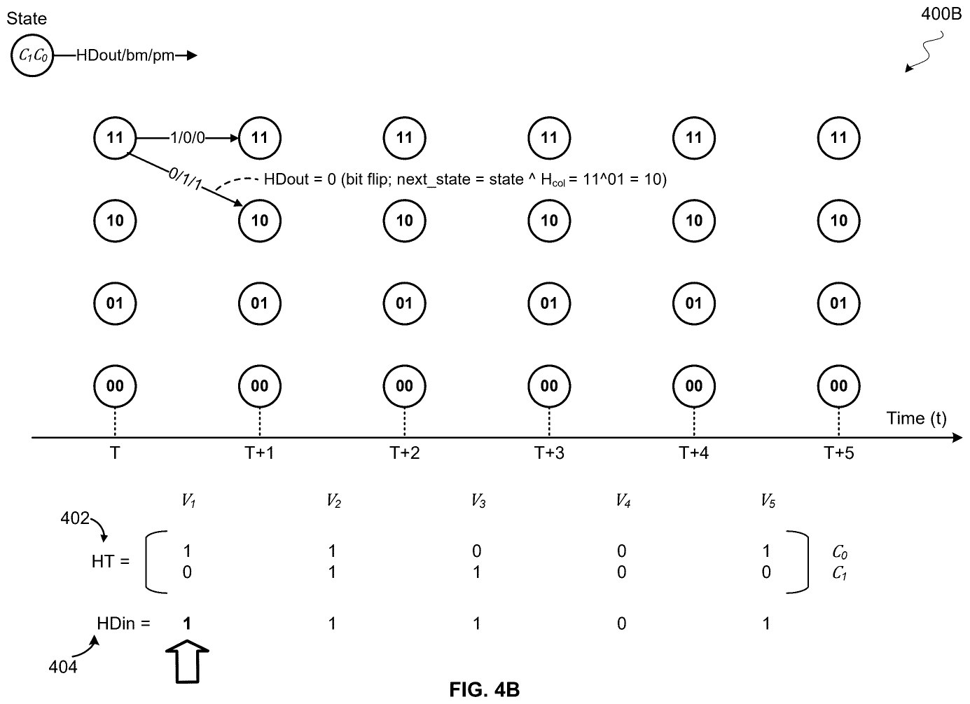

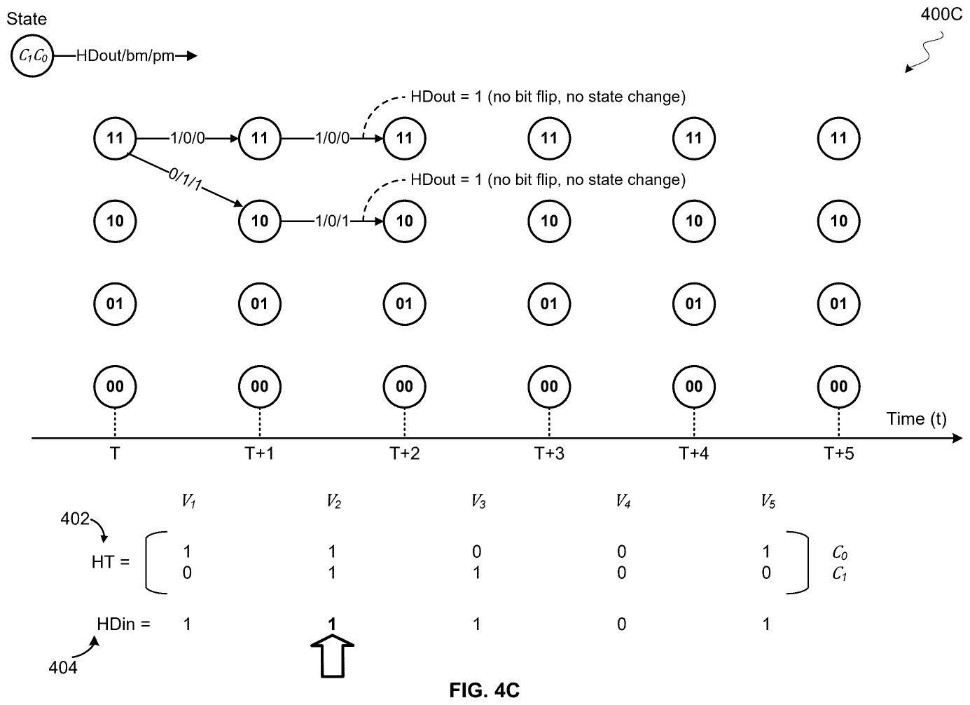

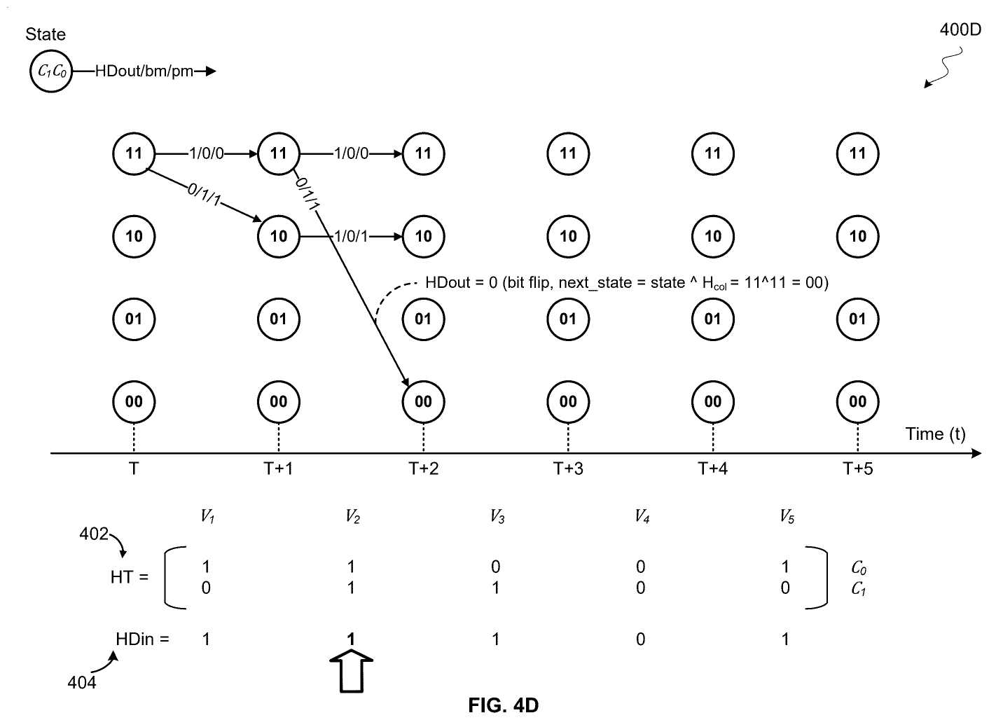

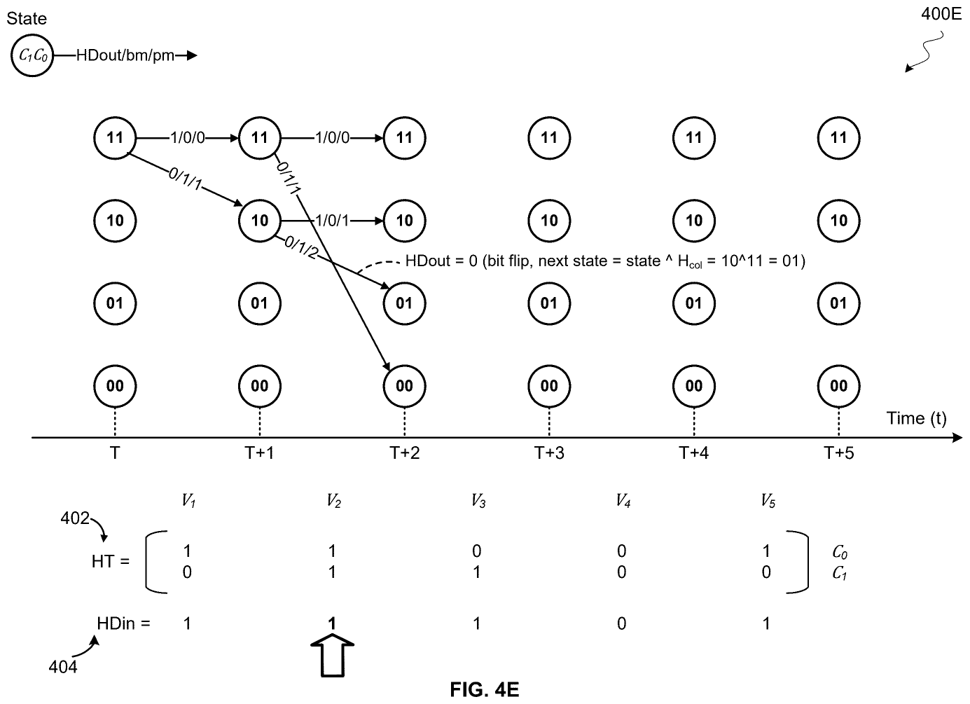

FIGS. 4A-4E illustrate an example of a series of state transitions for a trellis decoding process to resolve a set of unsatisfied check nodes, according to an aspect of the disclosure.

Referring to diagram 400A shown in FIG. 4A, the BF decoder 330 may provide a sub-matrix HT 402 and an input HDᵢₙ 404 to the trellis decoder 360. As shown in FIG. 4A, the sub-matrix HT 402 can be a 2×5 matrix, where columns V1, V2, V3, V4, and V5 represent variable nodes, and rows C0, and C1 represent check nodes. The check nodes C0 and C1 are unsatisfied check nodes from a set of check nodes that may comprise unsatisfied and satisfied check nodes. In some examples, the variable nodes V1, V2, V3, V4, and V5 and the set of check nodes comprising the unsatisfied check nodes C0 and C1 are selected from a parity check matrix, similar to the parity check matrix H 200 in FIG. 2A.

The two check nodes C1 and C0 can represent 4 possible states 00, 01, 10, and 11, where the most significant bit (MSB) represents the value of check node C1 and the least significant bit (LSB) represents the value of check node C0, e.g., C1C0. As shown on a time index in FIG. 4A, the input bit sequence HDᵢₙ 404 can be provided by the BF decoder 330 to the trellis decoder 360, e.g., one bit at a time, corresponding to each the variable nodes V1, V2, V3, V4, and V5. The trellis decoder 360 may provide outputs HDₒᵤₜ, a branch metric (bm), and a path metric (pm) for each bit of HDᵢ 404 received from the BF decoder 330, as indicated by HDₒᵤₜ/bm/pm for each state transition stage represented by the corresponding variable node.

For each of the 5 columns (e.g., n=5) of the sub-matrix HT 402, a corresponding value of the variable node may be considered for transitioning to the next (or destination) state as an input bit HDᵢₙ 404 is received from the BF decoder 330. For each input bit HDᵢₙ 404, the bit value of HDₒᵤₜ can stay the same as HDᵢₙ 404 or can be flipped. In the example shown in FIG. 4A, the first state transition at a time t=T, the source state s(T) is 11 indicating that a particular codeword received by the BF decoder 330 resulted in the incorrect values 11 for both C1 and C0 (e.g., C1C0). In this state, the bolded bit value of HDᵢₙ 404 corresponding to V1 is 1. If the trellis decoder 360 does not flip the bit value of HDᵢₙ 404 (no bit flip), the value of HDₒᵤₜ stays the same as HDᵢₙ (e.g., HDₒᵤₜ=HDᵢₙ=1), and the next state s(T+1) does not change. Since the next state stays the same as the source state, there is no branch taken, and therefore, in this case, the bm and the pm are 0, as indicated by “1/0/0” for the state transition stage represented by V1.

Referring to diagram 400B shown in FIG. 4B, when the source state s(T) is 11, and the value of HDₒᵤₜ is flipped to 0 for HDᵢₙ 404=1, the next state s(T+1) is determined by performing a bitwise XOR operation of the source state s(T) and the value of the first column 01 (e.g., n is 1) corresponding to variable node V1. Thus, the next state s(T+1) becomes 10 from the XOR of 11 and 01. In this case, the trellis decoder 360 provides HDₒᵤₜ/bm/pm as “0/1/1” for the state transition stage indicating HDₒᵤₜ to be 0 (bit flip), bm as 1 due to the change in the state, and the pm as 1 due to the bm being 1.

Referring to diagram 400C shown in FIG. 4C, for an input value of 1 for variable node V2 of HDᵢₙ 404, the second state transition at time T+1 from the source states 11 and 10 are determined based on the column values corresponding to the variable node V2. For state 11, if HDₒᵤₜ stays the same as HDᵢₙ(e.g., no bit flip), the next state s(T+2) does not change and stays at the source state 11. Thus, in this case, the bm and the pm are 0, as indicated by “1/0/0” for the state transition stage corresponding to the variable node V2. Similarly, for state 10, if HDₒᵤₜ stays the same as HDᵢₙ (no bit flip), the next state s(T+2) does not change and stays at the source state 10. Thus, in this case, the trellis decoder 360 provides HDₒᵤₜ/bm/pm as “1/0/1” for the state transition stage indicating HDₒᵤₜ to be 1 (no bit flip), bm as 0 due to no change in the state, and the pm as 1 due to the accumulation of pm from the previous state transition stage shown in FIG. 4B.

Referring to diagram 400D shown in FIG. 4D, when the source state s(T+1) is 11, and the bit value of HDₒᵤₜ is flipped to 0 for HDᵢₙ 404=1, the next state s(T+2) is determined by performing a bitwise XOR operation of the source state s(T+1) and the value of the second column 11 (e.g., n is 2) corresponding to the variable node V2. Thus, the next state s(T+2) becomes 00 from the XOR of 11 and 11. In this case, the trellis decoder 360 provides HDₒᵤₜ/bm/pm as “0/1/1” for the state transition stage indicating HDₒᵤₜ to be 0 (bit flip), bm as 1 due to the change in the state, and the pm as 1 due to the bm being 1.

Referring to diagram 400E shown in FIG. 4E, when the source state s(T+1) is 10, and the value of HDₒᵤₜ is flipped to 0 for HDᵢₙ 404=1, the next state s(T+2) is determined by performing a bitwise XOR operation of the source state s(T+1) and the value of the second column 11 (e.g., n is 2) corresponding to the variable node V2. Thus, the next state s(T+2) becomes 01 from the XOR of 10 and 11. In this case, the trellis decoder 360 provides HDₒᵤₜ/bm/pm as “0/1/2” for the state transition stage indicating HDₒᵤₜ to be 0 (bit flip), bm as 1 due to the change in the state, and the pm as 2 due to the bm being 1 and the accumulation of pm from the previous state transition stage shown in FIG. 4B.

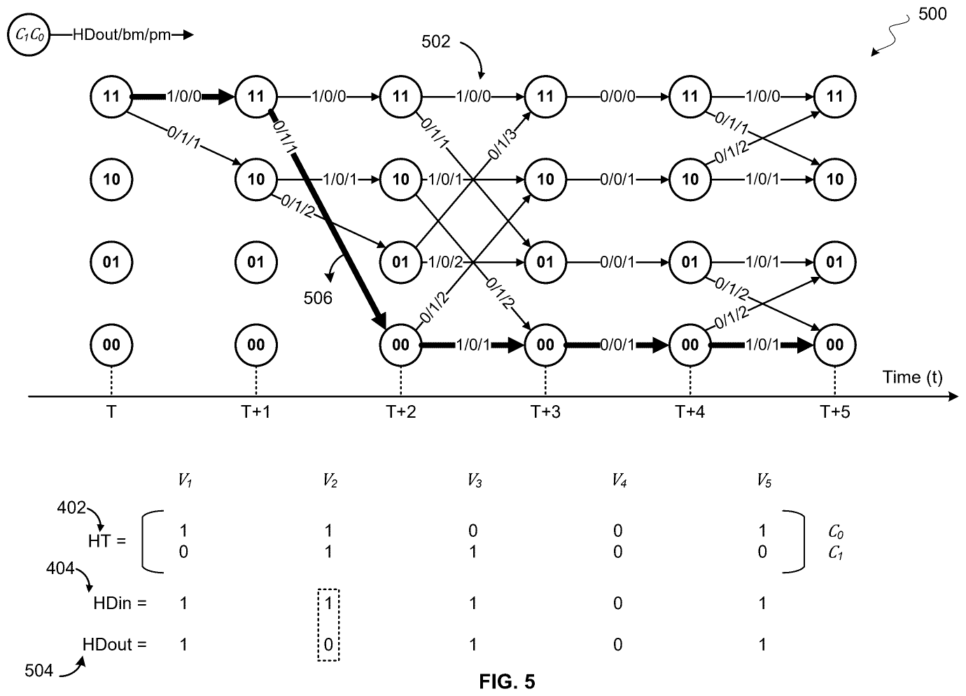

FIG. 5 illustrates an example of a trellis decoding process 500 that generates a trellis 502 with a lowest path cost metric, according to some embodiments.

The trellis 502 may be generated starting with the trellis decoding process described with reference to FIGS. 4A, 4B, 4C, 4D, and 4E by considering each column of the sub-matrix HT 402 corresponding to the same bit value or bit-flipped value of the HDᵢₙ 404. Thus, for 5 columns of the sub-matrix HT 402 and for each bit value of the HDᵢₙ 404 (e.g., 0 or 1), 5 state transition stages may occur starting with the initial state of 11 for (C1,C0). For example, the column vector corresponding to the variable node V3 is considered for the bit value of 1 for HDᵢₙ 404 at a time T+2, the column vector corresponding to the variable node V4 is considered for the bit value of 0 for HDᵢₙ 404 at a time T+3, and the column vector corresponding to the variable node V5 is considered for the bit value of 1 for HDᵢₙ 404 at a time T+4. For each state transition, the trellis decoder 360 provides the HDₒᵤₜ/bm/pm values, which can be used to determine the shortest path through the trellis 502 that has a corrected value of HDₒᵤₜ 504.

As shown in FIG. 5, a bolded path 506 starting with the state 11 and ending at a state 00 at a time T+5 through the states 11, 00, 00, and 00 provides the shortest path with the final pm value being 1. The bit value of HDₒᵤₜ 504 matches with the bit value of HDᵢₙ 402 for the variable nodes V1, V3, V4, and V5, except for the variable node V2. For example, the bit value of HDₒᵤₜ 504 corresponding to the variable node V2 is flipped from the bit value of HDᵢₙ 404 as part of the trellis decoding process. Thus, the trellis decoder 360 can provide the correct value of the HDₒᵤₜ 504 (e.g., 0) to the BF decoder 330, which can be used by the BF decoder 330 in a next iteration of the BF decoding to decode the LDPC codeword. Note that the last state 00 of the bolded path 506 has another branch coming in from the state 01 with the state transition stage 0/1/2,/ which has the pm value of 2 due to the accumulation of pm from the previous state transition stages. Since the value of pm for this path is higher than the bolded path 506, the HDₒᵤₜ 504 is selected from the winner branch indicated by the bolded path 506.

Note that FIGS. 4A-4E and 5 are described using two check nodes C1 and C0, however, techniques described herein can be applied to more than two check nodes. Furthermore, the set of unsatisfied check nodes may be partitioned into smaller subsets, which can be decoded by multiple trellis decoders executing concurrently with the BF decoder. The multiple trellis decoders may include a plurality of trellis decoders having states represented by overlapping subsets of the set of unsatisfied check nodes, and state transition stages represented by the variable nodes. In some examples, bit values of variable nodes having conflicting bit values determined by different trellis decoders can be decided by a majority vote of the trellis decoders.

It should also be noted that in the example of FIGS. 4A-4E and 5, the initial state is “11” indicating that both check nodes are not satisfied. It is also possible to employ the trellis decoding with a combination of satisfied and unsatisfied check nodes. In some implementations, each satisfied check node may share a minimum threshold number of connected variable nodes with at least one unsatisfied check node. When a combination of unsatisfied and satisfied check nodes are used, the initial state may include one or more “0” values representing the satisfied check node(s). In any event, the ending state will be all zeros representing a set of satisfied check nodes.

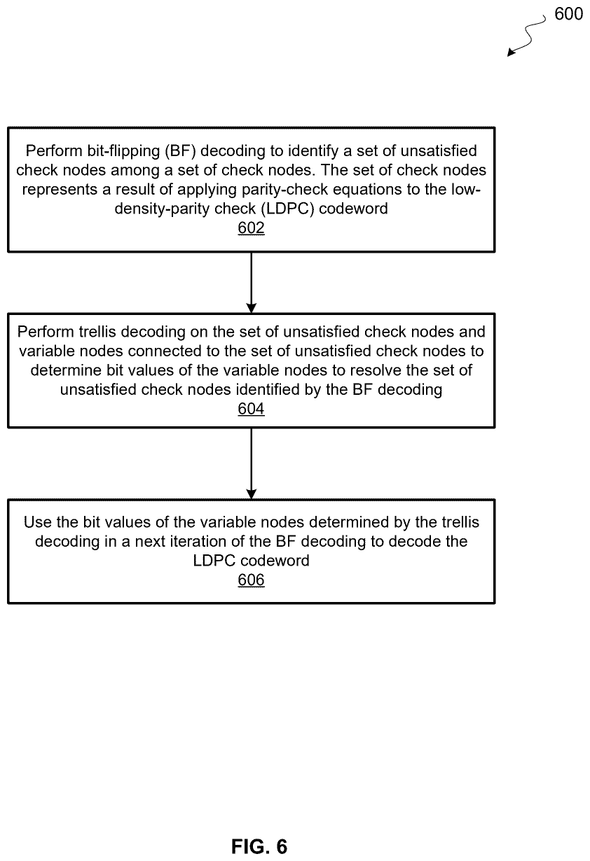

FIG. 6 is a flow diagram of an example process 600 for decoding a codeword, in accordance with certain embodiments of the present disclosure. The process 600 can be performed by a trellis-assisted BF decoder that receives ECCs (e.g., LDPC codes) for decoding. For example, the process 600 can be performed by the BF decoder 330.

At operation 602, BF decoding is performed to identify a set of unsatisfied check nodes among a set of check nodes. The set of check nodes represents a result of applying parity-check equations to the LDPC codeword. For example, parity-check equations are applied to the bit-values of a received codeword to calculate an initial syndrome. Each check node represents a corresponding bit of a syndrome. The checksum (also known as syndrome weight) for any particular syndrome can be computed by summing the bit-values of all the bits in the syndrome. The BF decoder 330 may perform iterative decoding to compute a new syndrome for each subsequent iteration, and update the bit-values of variable nodes. A check node is unsatisfied when the bit-value of the check node is one. A syndrome consisting entirely of zeros is associated with an error-free codeword. As described with the example above in reference to FIGS. 4A-4E and 5, the set of unsatisfied check nodes may include the check nodes C1 and C0 identified by the BF decoder 330 after an iterative decoding process. The BF decoder 300 may provide the sub-matrix HT 402 to the trellis decoder 360 to perform trellis decoding, which may be performed concurrently with the BF decoding.

At operation 604, trellis decoding can be performed on the set of unsatisfied check nodes and variable nodes connected to the set of unsatisfied check nodes to determine bit values of the variable nodes to resolve the set of unsatisfied check nodes identified by the BF decoding. As an example, trellis decoding may include executing the trellis decoder 360 having states represented by the set of unsatisfied check nodes C1 and C0, and state transition stages represented by the variable nodes V1, V2, V3, V4, and V5. The bit values of the variable nodes are determined based on a lowest path cost metric of the trellis decoding to resolve the set of unsatisfied check nodes. As described with the example in reference to FIGS. 4A-4E and 5, the trellis decoder 360 may be executed to perform trellis decoding on the states (C1C0), and the variable nodes V1, V2, V3, V4, and V5 connected to the check nodes C1 and C0 by considering each column of the sub-matrix HT 402 corresponding to the input bit HDᵢₙ 404. The bit values of the variable nodes V1-V5 are determined by the trellis decoder 360 as represented by HDₒᵤₜ 504, and provided to the BF decoder 330. The bolded path 506 through the trellis 502 provides the lowest path cost metric (e.g., pm is 1) of the trellis decoding that resolves the bit value of HDₒᵤₜ 504 corresponding to the variable node V2, as shown in FIG. 5.

At operation 606, the bit values of the variable nodes determined by the trellis decoding are used in a next iteration of the BF decoding to decode the LDPC codeword. The trellis decoder 360 provides the corrected bit values for the variable node V2 to the BF decoder 330, which is used by the BF decoder 360 in the next iteration of the BF decoding to decode the LDPC codeword. Thus, trellis-assisted BF decoding can be used to resolve the set of unsatisfied check nodes identified by the BF decoding by executing the trellis decoder 360 in parallel or concurrently with the BF decoder 330 to avoid introducing additional delays.

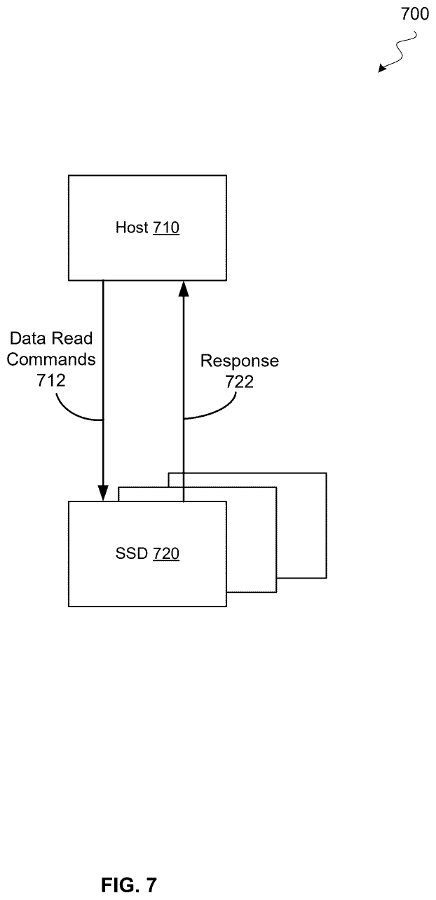

FIG. 7 illustrates an example architecture of a computer system 700, in accordance with certain embodiments of the present disclosure. In an example, the computer system 700 includes a host 710 and one or more solid state drives (SSDs) 720. The host 710 stores data on behalf of clients, e.g., the SSDs 720. The data is stored in an SSD as codewords for ECC protection. For instance, the SSD can include an error correction system comprising one or more ECC encoders (e.g., the LDPC encoder of FIG. 1).

The host 710 can receive a request from a client for the client's data stored in the SSDs 700. In response, the host sends data read commands 712 to the SSDs 720 as applicable. Each of the SSDs 720 processes the received data read command and sends a response 722 to the host 710 upon completion of the processing. The response 722 can include the read data and/or a decoding failure. In an example, each of the SSDs includes at least one ECC decoder (e.g., one or more of the LDPC decoder of FIG. 1). Further, at least one of the SSDs 720 may include a trellis-assisted BF decoder (e.g., the BF decoder 330 and the trellis decoder 360 of FIG. 3). In particular, some or all of the SSDs 720 may include a trellis-assisted BF decoder that may utilize a trellis decoder to correct errors in a small set of unsatisfied check nodes for an irregular LDPC codeword in parallel while the BF decoder is performing the BF decoding on the irregular LDPC codeword.

Processing the data read command and sending the response 722 includes decoding by the ECC decoder(s) the codewords stored in the SSD to output the read data and/or the decoding failure. Some of the codewords may be decoded by a BF decoder in parallel with a trellis decoder, as described with reference to FIGS. 4A-4E, and FIG. 5.

In an example where an SSD 720 includes a BF decoder and one or more additional ECC decoders, the SSD may be configured to attempt an initial decoding of its stored codewords using the BF decoder. The one or more additional ECC decoders can remain inactive while the BF decoder is decoding. According to some aspects of the disclosure, one or more trellis decoders can be executed in parallel with the BF decoder to perform error correction for a small set of unsatisfied check nodes to accelerate the decoding process and improve the correction performance of the optimized parity check metrics for the MS decoders.

If the decoding by the BF decoder is unsuccessful, the SSD may select one of the additional ECC decoders (e.g., based on a hierarchical order) for performing decoding. Thus, the one or more additional ECC decoders may act as backup decoders in the event that the BF decoder cannot fully decode a codeword. A backup decoder need not process all the codewords input to the BF decoder. Instead, in some examples, the input to a backup decoder is a subset of the input to a previously selected decoder, where the subset corresponds to codewords that the previously selected decoder failed to fully decode. Further, some of the additional ECC decoders may be operated in parallel with the BF decoder to perform parallel processing of codewords. For example, as discussed below in connection with FIG. 3, an incoming set of codewords can be distributed across a BF decoder and an MS decoder so that each decoder processes a distinct subset of codewords.

Generally, an SSD can be a storage device that stores data persistently or caches data temporarily in nonvolatile semiconductor memory and is intended for use in storage systems, servers (e.g., within datacenters), and direct-attached storage (DAS) devices. A growing number of applications need high data throughput and low transaction latency, and SSDs are used as a viable storage solution to increase performance, efficiency, and reliability. SSDs generally use NAND flash memory and deliver higher performance and consume less power than spinning hard-disk drives (HDDs). NAND Flash memory has a number of inherent issues associated with it, the two most important include a finite life expectancy as NAND Flash cells wear out during repeated writes, and a naturally occurring error rate. SSDs can be designed and manufactured according to a set of industry standards that define particular performance specifications, including latency specifications, to support heavier write workloads, more extreme environmental conditions and recovery from a higher bit error rate (BER) than a client SSD (e.g., personal computers, laptops, and tablet computers).

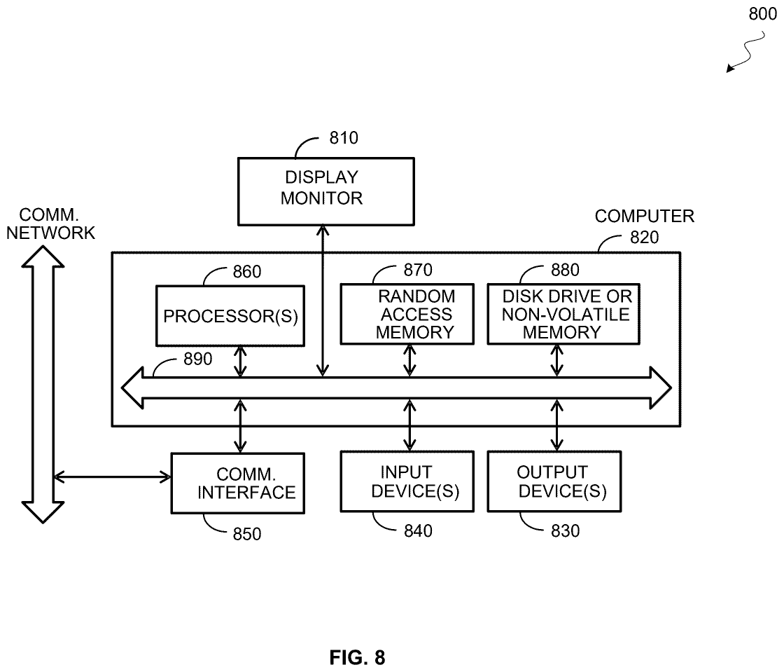

FIG. 8 illustrates a computer system 800 usable for implementing one or more embodiments of the present disclosure. FIG. 8 is merely an example and does not limit the scope of the disclosure as recited in the claims. As shown in FIG. 8, the computer system 800 may include a display monitor 810, a computer 820, user output devices 830, user input devices 840, a communications interface 850, and/or other computer hardware or accessories. The computer system 800 or select components of the computer system 800 can be used to implement the error correction system 300 of FIG. 3.

As shown in FIG. 8, the computer 820 may include one or more processors 860 that communicate with a number of peripheral devices via a bus subsystem 890. These peripheral devices may include the user output devices 830, the user input devices 840, the communications interface 850, and a storage subsystem, such as a random access memory (RAM) 870 and a disk drive or non-volatile memory 880.

The user input devices 840 include all possible types of devices and mechanisms for inputting information to the computer 820. These may include a keyboard, a keypad, a touch screen incorporated into the display, audio input devices such as voice recognition systems, microphones, and other types of input devices. In various embodiments, the user input devices 840 are typically embodied as a computer mouse, a trackball, a track pad, a joystick, a wireless remote, a drawing tablet, a voice command system, an eye tracking system, and the like. The user input devices 840 typically allow a user to select objects, icons, text and the like that appear on the monitor 810 via a command such as a click of a button or the like.

The user output devices 830 include all possible types of devices and mechanisms for outputting information from the computer 820. These may include a display (e.g., the monitor 810), non-visual displays such as audio output devices, etc.

The communications interface 850 provides an interface to other communication networks and devices. The communications interface 850 may serve as an interface for receiving data from and transmitting data to other systems. Embodiments of the communications interface 850 typically include an Ethernet card, a modem (telephone, satellite, cable, ISDN), (asynchronous) digital subscriber line (DSL) unit, FireWire interface, USB interface, and the like. For example, the communications interface 850 may be coupled to a computer network, to a FireWire bus, or the like. In other embodiments, the communications interfaces 850 may be physically integrated on the motherboard of the computer 820, and may be a software program, such as soft DSL, or the like.

In various embodiments, the computer system 800 may also include software that enables communications over a network such as the HTTP, TCP/IP, RTP/RTSP protocols, and the like. In alternative embodiments of the present disclosure, other communications software and transfer protocols may also be used, for example IPX, UDP or the like.

The RAM 870 and the disk drive 880 are examples of tangible media configured to store data such as embodiments of the present disclosure, including executable computer code, human readable code, or the like. Other types of tangible media include floppy disks, removable hard disks, optical storage media such as CD-ROMS, DVDs and bar codes, semiconductor memories such as flash memories, non-transitory read-only-memories (ROMS), battery-backed volatile memories, networked storage devices, and the like. The RAM 870 and the disk drive 880 may be configured to store the basic programming and data constructs that provide the functionality of the present disclosure.

Software code modules and instructions that provide the functionality of the present disclosure may be stored in the RAM 870 and the disk drive 880. These software modules may be executed by the processor(s) 860. The RAM 870 and the disk drive 880 may also provide a repository for storing data used in accordance with the present disclosure.

The RAM 870 and the disk drive 880 may include a number of memories including a main random access memory (RAM) for storage of instructions and data during program execution and a read-only memory (ROM) in which fixed non-transitory instructions are stored. The RAM 870 and the disk drive 880 may include a file storage subsystem providing persistent (non-volatile) storage for program and data files. The RAM 870 and the disk drive 880 may also include removable storage systems, such as removable flash memory.

The bus subsystem 890 provides a mechanism for letting the various components and subsystems of the computer 820 communicate with each other as intended. Although the bus subsystem 890 is shown schematically as a single bus, alternative embodiments of the bus subsystem may utilize multiple busses.

It will be readily apparent to one of ordinary skill in the art that many other hardware and software configurations are suitable for use with the present disclosure. For example, the computer 820 may be a desktop, portable, rack-mounted, or tablet configuration. Additionally, the computer 820 may be a series of networked computers. In still other embodiments, the techniques described above may be implemented upon a chip or an auxiliary processing board.

Various embodiments of the present disclosure can be implemented in the form of logic in software or hardware or a combination of both. The logic may be stored in a computer readable or machine-readable non-transitory storage medium as a set of instructions adapted to direct a processor of a computer system to perform a set of steps disclosed in embodiments of the present disclosure. The logic may form part of a computer program product adapted to direct an information-processing device to perform a set of steps disclosed in embodiments of the present disclosure. Based on the disclosure and teachings provided herein, a person of ordinary skill in the art will appreciate other ways and/or methods to implement the present disclosure.

The data structures and code described herein may be partially or fully stored on a computer-readable storage medium and/or a hardware module and/or hardware apparatus. A computer-readable storage medium includes, but is not limited to, volatile memory, non-volatile memory, magnetic and optical storage devices such as disk drives, magnetic tape, CDs (compact discs), DVDs (digital versatile discs or digital video discs), or other media, now known or later developed, that are capable of storing code and/or data. Hardware modules or apparatuses described herein include, but are not limited to, application-specific integrated circuits (ASICs), field-programmable gate arrays (FPGAs), dedicated or shared processors, and/or other hardware modules or apparatuses now known or later developed.

The methods and processes described herein may be partially or fully embodied as code and/or data stored in a computer-readable storage medium or device, so that when a computer system reads and executes the code and/or data, the computer system performs the associated methods and processes. The methods and processes may also be partially or fully embodied in hardware modules or apparatuses, so that when the hardware modules or apparatuses are activated, they perform the associated methods and processes. The methods and processes disclosed herein may be embodied using a combination of code, data, and hardware modules or apparatuses.

Although the foregoing embodiments have been described in some detail for purposes of clarity of understanding, the disclosure is not limited to the details provided. There are many alternative ways of implementing the disclosure. The disclosed embodiments are illustrative and not restrictive.

What is claimed is:

1. A method for decoding a low-density parity-check (LDPC) codeword, the method implemented on a computing device and comprising:
performing bit-flipping (BF) decoding to identify a set of unsatisfied check nodes among a set of check nodes, wherein the set of check nodes represents a result of applying parity-check equations to the LDPC codeword;
performing trellis decoding on the set of unsatisfied check nodes and variable nodes connected to the set of unsatisfied check nodes to determine bit values of the variable nodes to resolve the set of unsatisfied check nodes identified by the BF decoding; and
using the bit values of the variable nodes determined by the trellis decoding in a next iteration of the BF decoding to decode the LDPC codeword.

2. The method of claim 1, wherein the bit values of the variable nodes are determined based on a lowest path cost metric of the trellis decoding to resolve the set of unsatisfied check nodes.

3. The method of claim 1, wherein the trellis decoding includes executing a trellis decoder having states represented by the set of unsatisfied check nodes, and state transition stages represented by the variable nodes.

4. The method of claim 1, wherein the BF decoding is performed concurrently with the trellis decoding.

5. The method of claim 1, wherein the trellis decoding includes concurrently executing multiple trellis decoders.

6. The method of claim 5, wherein each of the multiple trellis decoders has states represented by a different subset of the set of unsatisfied check nodes, and state transition stages represented by the variable nodes.

7. The method of claim 5, wherein each of the multiple trellis decoders has states represented by at least one unsatisfied check node in the set of unsatisfied check nodes and at least one satisfied check node, and state transition stages represented by the variable nodes.

8. The method of claim 7, wherein each of the at least one satisfied check node shares a minimum threshold number of connected variable nodes with an unsatisfied check node.

9. The method of claim 5, wherein the multiple trellis decoders include a plurality of trellis decoders having states represented by overlapping subsets of the set of unsatisfied check nodes, and state transition stages represented by the variable nodes.

10. The method of claim 9, wherein bit values of variable nodes having conflicting bit values determined by different trellis decoders are decided by a majority vote of the trellis decoders.

11. A device comprising:
a memory storing a low-density parity-check (LDPC) codeword; and
one or more processing units operable to:
perform bit-flipping (BF) decoding to identify a set of unsatisfied check nodes among a set of check nodes, wherein the set of check nodes represents a result of applying parity-check equations to the LDPC codeword read from the memory;
perform trellis decoding on the set of unsatisfied check nodes and variable nodes connected to the set of unsatisfied check nodes to determine bit values of the variable nodes to resolve the set of unsatisfied check nodes identified by the BF decoding; and
use the bit values of the variable nodes determined by the trellis decoding in a next iteration of the BF decoding to decode the LDPC codeword.

12. The device of claim 11, wherein the bit values of the variable nodes are determined based on a lowest path cost metric of the trellis decoding to resolve the set of unsatisfied check nodes.

13. The device of claim 11, wherein performing the trellis decoding includes executing a trellis decoder having states represented by the set of unsatisfied check nodes, and state transition stages represented by the variable nodes.

14. The device of claim 11, wherein the BF decoding is performed concurrently with the trellis decoding.

15. The device of claim 11, wherein the trellis decoding includes concurrently executing multiple trellis decoders.

16. The device of claim 15, wherein each of the multiple trellis decoders has states represented by a different subset of the set of unsatisfied check nodes, and state transition stages represented by the variable nodes.

17. The device of claim 15, wherein each of the multiple trellis decoders has states represented by at least one unsatisfied check node in the set of unsatisfied check nodes and at least one satisfied check node, and state transition stages represented by the variable nodes.

18. The device of claim 17, wherein each of the at least one satisfied check node shares a minimum threshold number of connected variable nodes with an unsatisfied check node.

19. The device of claim 15, wherein the multiple trellis decoders include a plurality of trellis decoders having states represented by overlapping subsets of the set of unsatisfied check nodes, and state transition stages represented by the variable nodes.

20. The device of claim 19, wherein bit values of variable nodes having conflicting bit values determined by different trellis decoders are decided by a majority vote of the trellis decoders.
